(19) United States
(12) Patent Application Publication
(10) Pub. No.: US 2025/0031311 A1
(43) Pub. Date: Jan. 23, 2025

(54) Electronic Component Mounting Board

(71) Applicant: ROHM CO., LTD., KYOTO-SHI (JP)

(72) Inventors: KAORU MURAKI, KYOTO-SHI (JP); MASATOSHI NAKANISHI, KYOTO-SHI (JP)

(21) Appl. No.: 18/771,130

(22) Filed: Jul. 12, 2024

(30) Foreign Application Priority Data
Jul. 19, 2023 (JP) 2023-117401

(51) Int. Cl. H05K 1/18; H05K 3/28

(52) U.S. Cl. CPC H05K 1/181; H05K 3/284; H05K 2201/09036; H05K 2201/10159

(57) ABSTRACT

The present disclosure provides an electronic component mounting board. The electronic component mounting board includes a printed circuit board, an electronic component and a sealing resin. The printed circuit board has a main surface. The electronic component is mounted on the main surface. The sealing resin is disposed on the main surface to cover the electronic component. A groove is formed over the main surface, and the groove extends across a region between a side of the main surface and the electronic component in a plan view.

### TECHNICAL FIELD

The present disclosure relates to an electronic component mounting board.

### BACKGROUND

For example, Japanese Patent Publication No. 2022-112463 (patent document 1) discloses a thermal print head. The thermal print head disclosed in patent document 1 includes a connecting board. Various electronic components are mounted on the connecting board.

### PRIOR ART DOCUMENT

### Patent Publication

[Patent document 1] Japan Patent Publication No. 2022-112463

### BRIEF DESCRIPTION OF THE DRAWINGS

FIG. 1 is a plan view of an electronic component mounting board 100.

FIG. 2 is a partial enlarged diagram of a region II in FIG. 1.

FIG. 3 is a cross-sectional diagram along a section line III-III in FIG. 2.

FIG. 4 is a cross-sectional diagram along a section line IV-IV in FIG. 2.

FIG. 5 is an enlarged plan view of the electronic component mounting board 100 of a variation example.

FIG. 6 is an enlarged plan view of an electronic component mounting board 200.

FIG. 7 is a cross-sectional diagram along a section line VII-VII in FIG. 6.

### DETAILED DESCRIPTION OF THE EMBODIMENTS

Details of embodiments of the present disclosure are described with reference to the accompanying drawings below. The same or equivalent parts are denoted by the same numerals or symbols in the accompanying drawings below, and repeated description is omitted.

### First Embodiment

A component mounting board of the first embodiment is described below. The component mounting board of the first embodiment is set as an electronic component mounting board 100.

### <Configuration of Electronic Component Mounting Board 100>

The configuration of the electronic component mounting board 100 is described below.

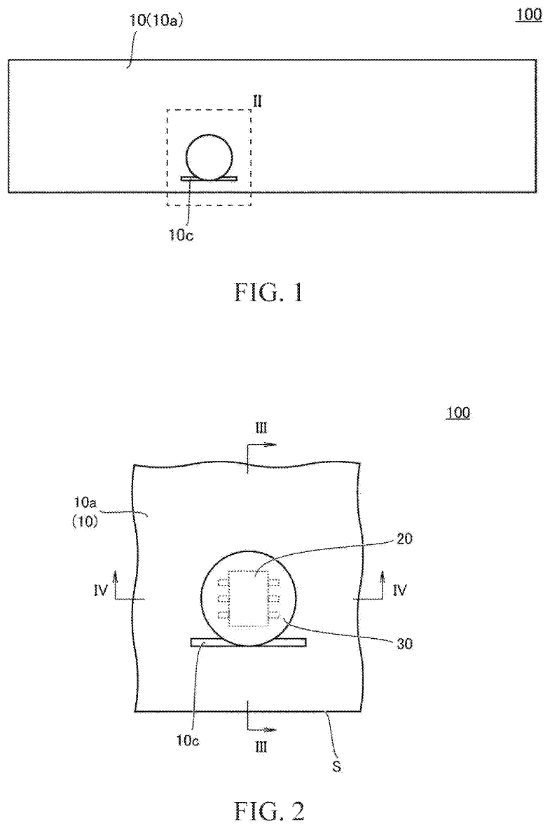

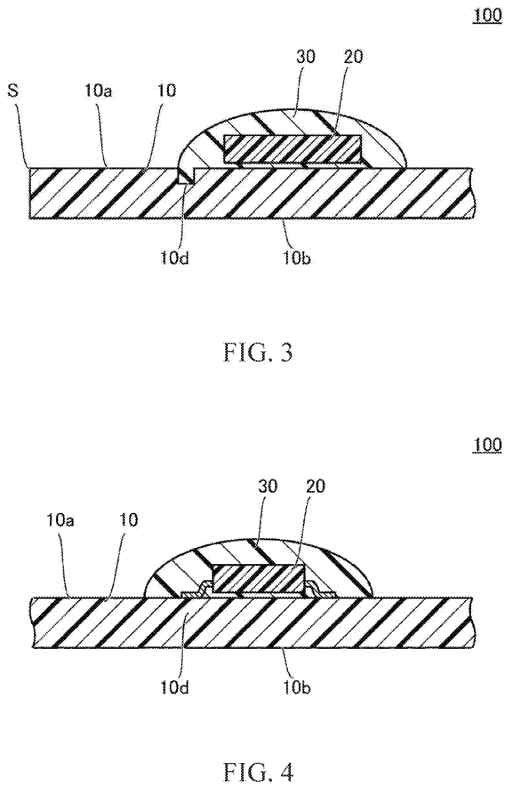

FIG. 1 shows a plan view of the electronic component mounting board 100. FIG. 2 shows a partial enlarged diagram of a region II in FIG. 1. FIG. 3 shows a cross-sectional diagram along a section line III-III in FIG. 2. FIG. 4 shows a cross-sectional diagram along a section line IV-IV in FIG. 2. As shown in FIG. 1, FIG. 2, FIG. 3 and FIG. 4, the electronic component mounting board 100 includes a printed circuit board 10, an electronic component 20 and a sealing resin 30. The electronic component mounting board 100 is configured to use for, for example, a thermal print head. However, the use of the electronic component mounting board 100 is not limited to the example above.

The printed circuit board 10 has a main surface 10a and a main surface 10b. The main surface 10a and the main surface 10b are end surfaces of the printed circuit board 10 in a thickness direction. The main surface 10b is a surface opposite to the main surface 10a. The main surface 10a has, for example, a rectangular shape in the plan view. Although not shown, a wire is present on the main surface 10a, and the wire is covered by a solder resist. Moreover, a portion of the wire transforms to a pad exposed from the solder resist.

The electronic component 20 is mounted on the main surface 10a. More specifically, the electronic component 20 is, for example, a wire pad welded on the main surface 10a of the printed circuit board 10. The electronic component 20 is, for example, an integrated circuit (IC) having a memory. The memory of the IC has identification information of the thermal print head stored therein. However, the electronic component 20 is not limited to the example above.

A groove 10c is formed over the main surface 10a. The groove 10c extends across a region between a side (a side S) of the main surface 10a and the electronic component 20 in the plan view. A width of the groove 10c in a direction parallel to the side S is, for example, greater than a width of the electronic component 20 in the direction parallel to the side S. The groove 10c extends in a manner of being parallel to the side S in the plan view, for example.

The sealing resin 30 is disposed on the main surface 10a to cover the electronic component 20. The sealing resin 30 in an uncured state is poured so as to cover the electronic component 20, and is then cured by such as heating. Preferably, the sealing resin 30 covers a side surface of the electronic component 20 facing the side of the groove 10c. The sealing resin 30 is preferably also disposed in the groove 10c.

Preferably, an adherence strength between the sealing resin 30 and the electronic component 20 is greater than an adherence strength between the sealing resin 30 and the printed circuit board 10. The adherence strength between the sealing resin 30 and the electronic component 20 and the adherence strength between the sealing resin 30 and the printed circuit board 10 are measured by a method below.

First of all, a first sample and a second sample are prepared. A surface of the first sample is analogous to a surface of the printed circuit board 10. That is to say, the surface of the first sample is formed of a solder resist. A surface of the second sample is analogous to a surface of the electronic component 20. That is to say, the surface of the second sample is formed of a mold resin of the electronic component 20. Secondly, the sealing resin 30 is disposed on the surface of the first sample and the surface of the second sample. Thirdly, the adherence strength between the surface of the first sample and the surface of the second sample of the sealing resin 30 is measured by measuring a tensile strength using a tensile force meter. The measurement result is regarded as the adherence strength between the sealing resin 30 and the electronic component 20 and the adherence strength between the sealing resin 30 and the printed circuit board 10.

### Variation Examples

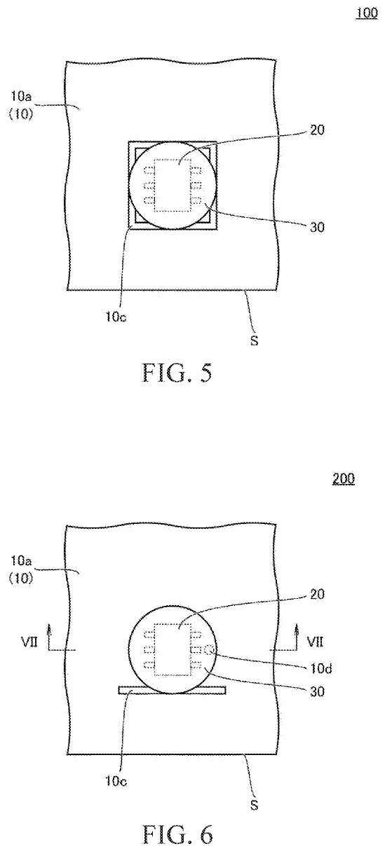

FIG. 5 shows an enlarged plan view of an electronic component mounting board 100 of a variation example. As shown in FIG. 5, the groove 10c can also be formed to surround the electronic component 20 in the plan view. In the description above, the groove 10c is formed over the main surface 10a; however, the groove may not be formed over the main surface 10a. In this case, the electronic component mounting board 100 is configured to use for a thermal print head, and the electronic component 20 is an IC having a memory with identification information of the thermal print head stored therein.

### <Effects of Electronic Component Mounting Board 100>

The effects of the electronic component mounting board 100 are described below.

When the electronic component 20 is an IC having a memory with identification information of a thermal print head stored therein, the identification information can be used to ensure traceability of the thermal print head and avoid mounting similar products on a printer.

When the electronic component 20 is exposed from the printed circuit board 10, since a third party can easily learn the existence of the electronic component 20, similar products can be made by separating and further analyzing the electronic component 20 and the printed circuit board 10. In the electronic component mounting board 10, because the electronic component 20 is covered by the sealing resin 30, it is difficult for a third party to learn the existence of the electronic component 20. Moreover, it is also difficult to separate the electronic component 20 from the printed circuit board 10, and so it is feasible to prevent a third party from making similar products.

When the sealing resin 30 exists in a small amount, sometimes the sealing resin 30 cannot fully cover the electronic component 20, such that a portion of the electronic component 20 is exposed from the sealing resin 30. On the other hand, if the amount of the sealing resin 30 is increased, the sealing resin 30 sometimes can overflow to the vicinity of the side S, and the sealing resin 30 can then interfere with other components when other components (for example, a lid) are mounted. In the electronic component mounting board 100, since the groove 10c is formed across the region between the side S and the electronic component 20 in the plan view, the sealing resin 30 is deposited in the groove 10c and so overflow of the sealing resin 30 can be suppressed.

By forming the groove 10c and adequately providing the sealing resin 30, the electronic component 20 can be prevented from being exposed (including from being exposed from the side surface of the electronic component 20 facing the side of the groove 10c) and can be covered by the sealing resin 30. Moreover, by forming the groove 10c and adequately providing the sealing resin 30, the sealing resin 30 can also enter the groove 10c to increase an adhesion area with the printed circuit board 10, so that the sealing resin 30 is less likely to strip off from the printed circuit board 10. As a result, it is made even more difficult for separating the electronic component 20 from the printed circuit board 10.

When the adherence strength between the sealing resin 30 and the electronic component 20 is greater than the adherence strength between the sealing resin 30 and the printed circuit board 10, even if the sealing resin 30 is stripped off from the printed circuit board 10, it remains difficult to strip off the sealing resin 30 from the electronic component 20. Thus, in this case, it is made more difficult for a third party to analyze the electronic component 20 and further make similar products. In addition, when the groove 10c surrounds the electronic component 20 in the plan view, the sealing resin 30 is suppressed from diffusing to the vicinity of the side S but is also suppressed from interfering with other parts on the printed circuit board 10.

### Second Embodiment

An electronic component mounting board of the second embodiment is described below. The component mounting board of the second embodiment is set as an electronic component mounting board 200. Moreover, details different from those of the electronic component mounting board 100 are primarily described, and repeated details are omitted herein.

### <Configuration of Electronic Component Mounting Board 200>

The configuration of the electronic component mounting board 200 is described below.

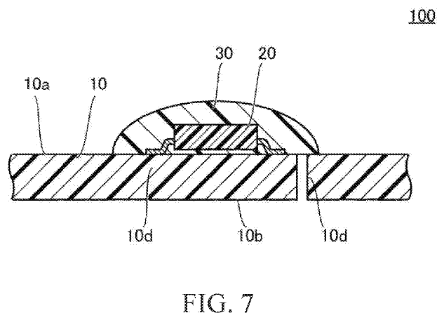

FIG. 6 shows an enlarged plan view of an electronic component mounting board 200. FIG. 7 shows a cross-sectional diagram along a section line VII-VII in FIG. 6. As shown in FIG. 6 and FIG. 7, the electronic component mounting board 200 includes a printed circuit board 10, an electronic component 20 and a sealing resin 30. With respect to the above, the configuration of the electronic component mounting board 200 in common with the configuration of the electronic component mounting board 100.

In the electronic component mounting board 200, a through hole 10d is formed in the printed circuit board 10. The through hole 10d extends through the printed circuit board 10 along a thickness direction. The through hole 10d is disposed around the electronic component 20 in the plan view. More specifically, the through hole 10d is located at a position overlapping with the sealing resin 30 in the plan view. With respect to the above, the configuration of the electronic component mounting board 200 is different from the configuration of the electronic component mounting board 100.

### <Effects of Electronic Component Mounting Board 200>

The effects of the electronic component mounting board 200 are described below.

During curing of the sealing resin 30, bubbles are sometimes formed on the surface of the sealing resin 30 due to the existence of air inside the sealing resin 30. The occurrence of such bubbles impairs the appearance of the sealing resin 30. Moreover, the electronic component 20 is sometimes exposed from marks of these bubbles as a result. In the electronic component mounting board 200, the through hole 10d is formed at a position overlapping with the sealing resin 30 in the plan view. Thus, air inside the sealing resin 30 passes through the through hole 10d and is released from the side of the main surface 10b, and so bubbles are unlikely to occur on the surface of the sealing resin 30. Therefore, according to the electronic component mounting board 200, appearance impairment of the sealing resin 30 accompanied with the bubbles caused by air inside the sealing resin 30 can be suppressed, or the electronic component 20 can be suppressed from being exposed from the marks of the bubbles.

### (Notes)

The configurations included in the embodiments of the present disclosure are listed below.

### <Note 1>

An electronic component mounting board, comprising:
a printed circuit board;
an electronic component; and
a sealing resin,
wherein the printed circuit board has a main surface,
the electronic component is mounted on the main surface,
the sealing resin is disposed on the main surface to cover the electronic component,
a groove is formed over the main surface, and
the groove extends across a region between a side of the main surface and the electronic component in a plan view.

### <Note 2>

The electronic component mounting board of Note 1, wherein the sealing resin covers a side surface of the electronic component facing a side of the groove.

### <Note 3>

The electronic component mounting board of Note 1 or Note 2, wherein the sealing resin is disposed within the groove.

### <Note 4>

The electronic component mounting board of any one of Notes 1 to 3, wherein the groove extends to surround the electronic component in the plan view.

### <Note 5>

The electronic component mounting board of any one of Notes 1 to 4, wherein a through hole is formed in the printed circuit board and extends through the printed circuit board along a thickness direction, the through hole is located at a position overlapping with the sealing resin in the plan view.

### <Note 6>

The electronic component mounting board of any one of Notes 1 to 5, wherein an adherence strength between the sealing resin and the electronic component is greater than an adherence strength between the sealing resin and the printed circuit board.

### <Note 7>

The electronic component mounting board of any one of Notes 1 to 6, wherein the electronic component mounting board is configured to use for a thermal print head, the electronic component is an IC having a memory, and the memory is operable to store identification information of the thermal print head.

### <Note 8>

An electronic component mounting board, comprising:
a printed circuit board;
an electronic component; and
a sealing resin,
wherein the printed circuit board has a main surface,
the electronic component is mounted on the main surface,
the sealing resin is disposed on the main surface to cover the electronic component,
the electronic component mounting board is configured to use for a thermal print head,
the electronic component is an IC having a memory, and
the memory is operable to store identification information of the thermal print head.

Although the embodiments of the present disclosure have been described above, the above-described embodiments can be modified in various ways. Furthermore, the scope of the present disclosure is not limited to the above-described embodiments. The scope of the present disclosure is defined by the claims, and is intended to include all modifications that are equivalent in meaning and scope to the claims.

1. An electronic component mounting board, comprising:
a printed circuit board;
an electronic component; and
a sealing resin,
wherein the printed circuit board has a main surface,
the electronic component is mounted on the main surface,
the sealing resin is disposed on the main surface to cover the electronic component,
a groove is formed over the main surface, and
the groove extends across a region between a side of the main surface and the electronic component in a plan view.

2. The electronic component mounting board of claim 1, wherein the sealing resin covers a side surface of the electronic component facing a side of the groove.

3. The electronic component mounting board of claim 1, wherein the sealing resin is disposed within the groove.

4. The electronic component mounting board of claim 1, wherein the groove extends to surround the electronic component in the plan view.

5. The electronic component mounting board of claim 1, wherein
a through hole is formed in the printed circuit board and extends through the printed circuit board along a thickness direction,
the through hole is located at a position overlapping with the sealing resin in the plan view.

6. The electronic component mounting board of claim 1, wherein
an adherence strength between the sealing resin and the electronic component is greater than an adherence strength between the sealing resin and the printed circuit board.

7. The electronic component mounting board of claim 1, wherein
the electronic component mounting board is configured to use for a thermal print head,
the electronic component is an IC having a memory, and
the memory is operable to store identification information of the thermal print head.

8. The electronic component mounting board of claim 2, wherein
the electronic component mounting board is configured to use for a thermal print head,
the electronic component is an IC having a memory, and
the memory is operable to store identification information of the thermal print head.

9. The electronic component mounting board of claim 3, wherein
the electronic component mounting board is configured to use for a thermal print head,
the electronic component is an IC having a memory, and
the memory is operable to store identification information of the thermal print head.

10. The electronic component mounting board of claim 4, wherein
the electronic component mounting board is configured to use for a thermal print head,
the electronic component is an IC having a memory, and
the memory is operable to store identification information of the thermal print head.

11. The electronic component mounting board of claim 5, wherein
the electronic component mounting board is configured to use for a thermal print head,
the electronic component is an IC having a memory, and
the memory is operable to store identification information of the thermal print head.

12. The electronic component mounting board of claim 6, wherein
the electronic component mounting board is configured to use for a thermal print head,
the electronic component is an IC having a memory, and
the memory is operable to store identification information of the thermal print head.

13. An electronic component mounting board, comprising:
a printed circuit board;
an electronic component; and
a sealing resin,
wherein the printed circuit board has a main surface,
the electronic component is mounted on the main surface,
the sealing resin is disposed on the main surface to cover the electronic component,
the electronic component mounting board is configured to use for a thermal print head,
the electronic component is an IC having a memory, and
the memory is operable to store identification information of the thermal print head.
